(19) United States
(12) Patent Application Publication
(10) Pub. No.: US 2013/0290594 A1
(43) Pub. Date: Oct. 31, 2013

(54) CORE-DRIVEN TRANSLATION AND LOOPBACK TEST

(71) Applicants: Timothy J. Callahan, Portland, OR (US); Brenton S. Jutras, Portland, OR (US)

(72) Inventors: Timothy J. Callahan, Portland, OR (US); Brenton S. Jutras, Portland, OR (US)

(21) Appl. No.: 13/977,369

(22) PCT Filed: Dec. 21, 2011
(86) PCT No.: PCT/US11/66406

§ 371 Date: Jun. 28, 2013

(51) Int. Cl. G01R 31/317; G06F 13/20

(52) U.S. Cl. CPC G01R 31/317; G06F 13/20
USPC 710/313; 702/117

(57) ABSTRACT

A translation and loopback test for input/output ports is described. In one example, a method includes receiving a test packet on an output of a high speed processor link, looping the test packet back to an input of the high speed processor link, and detecting the receipt of the looped back test packet to test operation of the high speed link.

### TECHNICAL FIELD

The present disclosure relates to the field of integrated circuit test and in particular to the test of data interfaces using a loop back.

### BACKGROUND

High speed data links in and out of a CPU (Central Processing Unit) are tested after the CPU is produced to ensure that the CPU is functional and meets expected quality levels. Higher speed links are more difficult to test and require more expensive test equipment, such as ATE (Automated Test Equipment). Typically, the die is attached to a testing socket or test bed and then programmed to produce commands or data on its output pins. These are received and analyzed by the test equipment. Similarly, the test equipment can be programmed to send data and commands to the CPU inputs. The CPU performance can then be analyzed by the CPU or by other equipment. In some tests, the commands and data fed to the CPU are designed so that the CPU produces a corresponding output on a different link. This output can be evaluated to determine whether the input was properly received.

Connected functional testers used for such tests are expensive and require time for the appropriate connections to be made. For PCIe and other high speed links, ATE (Automated Test Equipment) testers as well as system-based test initiatives typically use expensive custom PCIe ASICs (Application-Specific Integrated Circuits) on test cards.

### BRIEF DESCRIPTION OF THE DRAWINGS

Embodiments of the invention are illustrated by way of example, and not by way of limitation, in the figures of the accompanying drawings in which like reference numerals refer to similar elements.

FIG. 1 is a diagram of the flow of a test packet transaction according to an embodiment of the invention.

FIG. 2 is a diagram of the flow of a test packet transaction according to another embodiment of the invention.

FIG. 3 is a block diagram of a portion of a CPU showing a PCIe in and out pin with a loopback circuit according to an embodiment of the invention.

FIG. 4 is a process flow diagram of testing a link using a translation and loopback according to an embodiment of the invention.

FIG. 5 is a block diagram of a computer system in a test configuration according to an embodiment of the invention.

### DETAILED DESCRIPTION

Full coverage functional testing of PCIe (Peripheral Component Interconnect-express) and similar types of links can be built in to a CPU (Central Processing Unit). CPU cores generate a request packet to a PCI-express or DMI (Direct Media Interface) link which then translates the header & data of the packet creating a new request that either targets main memory with a read/write, or represents a message class packet. The resulting request is then looped back from the Tx (Transmit) port of the CPU to the Rx (Receive) port of the CPU, appearing as an inbound request to the CPU.

In one embodiment, the invention includes PCIe header translation logic to steer addresses from MMIO (Memory Mapped Input/Output) to main memory. A PCIe data drop mode aids with WRITE to READ conversion. PCIe data translation logic enables the injection of arbitrary PCIe request types. An ASM code configures the test mode and sends requests.

This approach can be used to provide deterministic coverage of non-deterministic interfaces such as PCIe in high volume situations. The testing can be performed using on-die testing instead of a connected functional tester. Expensive functional testers and external high speed test cards can therefore be eliminated. This includes ATE (Automated Test Equipment) testers as well as system-based test initiatives which typically use expensive custom PCIe ASICs (Application-Specific Integrated Circuits) on test cards.

This functional testing can be used with CPU packages that include a CPU in combination with graphics and chipset devices that are coupled with other external devices, such as memory (e.g., flash/DRAM (Dynamic Random Access Memory)/SRAM (Static Random Access Memory)/etc.) and circuit boards (e.g., motherboards, etc.)

PCIe translation and loopback has been used on legacy chipsets with a very limited test stimulus capability. Some embodiments of the present invention use CPU cores to generate the test stimulus, providing a programmable and high-speed mechanism for flooding PCIe links with request traffic. In addition, the CPU cores can “write” data to MMIO which the link then translates into PCIe request packets to be driven on the Rx port for the link.

In other words, CPU cores may be run in a test mode as PCIe test generators. The CPU cores generate outgoing WRITE requests as DATA writes from the CPU cores. These are stored to MMIO and translated to incoming READ requests. The incoming read requests then appear on the inbound PCIe port.

This allows software running from the CPU core to spoof all possible PCIe messages and request types. Running the test in an internal test mode from the CPU core also allows non-deterministic or asynchronous interfaces to be tested.

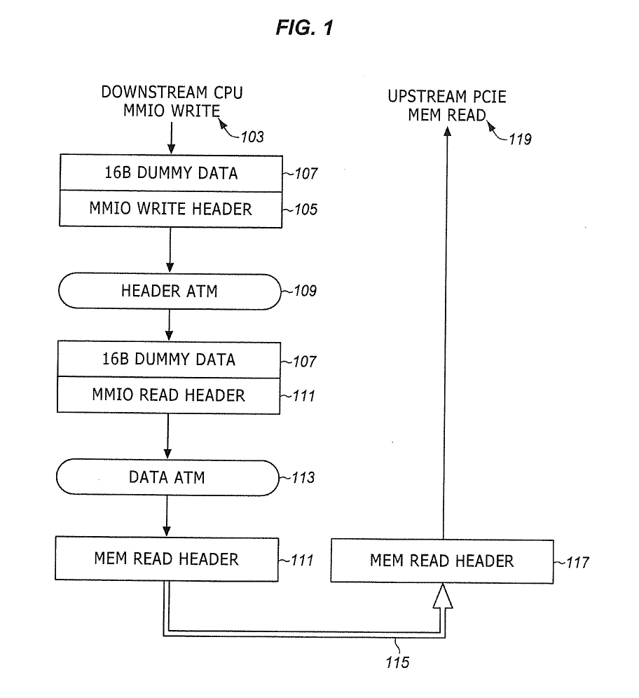

FIG. 1 is a message transactional diagram to show an example of converting an outgoing memory write to an incoming memory read. In this example, an outgoing MMIO WRITE is converted to an incoming MEM READ. Alternatively, an outgoing MMIO READ can be converted to an incoming MEM READ. Current outgoing bandwidth limitations for MMIO READ commands are lower than those for outgoing MMIO WRITE commands and for incoming MMIO READ commands so that the buffers on the inbound path will not be filled as much as with the MMIO WRITE. However, different types of test packets may be used to test different aspects of the link. The illustrated message transactions use outgoing WRITE credits (which are unlimited) to target incoming READ paths.

Referring again to FIG. 1, at 103 the CPU sends a downstream test packet, such as an MMIO WRITE request. This WRITE request as shown includes an MMIO WRITE header 105 and 16 bytes of dummy data 107. The address may be any address, however, in one embodiment of the invention the address is not a real, virtual, or physical address. The address is first selected to meet the standards for a WRITE header as considered by the downstream PCI port apparatus and second easily translated into a memory address for the read message below. The dummy data may be any data because, as shown below, this data will be stripped off before it has any impact on system operation. The header is processed through a header ATM (Attribute Translation Mode) 109 which translates the MMIO WRITE header into a memory READ header 111. The memory READ header still carries the 16 bytes of dummy data 107. The ATM is a special hardware logic device to quickly translate headers from MMIO type headers to memory type headers. In one example, fixed translate logic such as an XOR is used to translate the address. Different hardware logic may be used depending upon the particular implementation and intended tests.

After translating the header, or at the same time as translating the header, the dummy data 107 is translated using a data ATM 113. In this example the data ATM removes the dummy data to leave only the memory READ header 111. The dummy data is included so that the original MMIO WRITE command is processed as a standard MMIO WRITE command, however, for a memory READ no data is included. The dummy data having been stripped out from the command, the command is looped back 115 as a test packet to an input port.

FIG. 1 shows a downwards path representing a path towards the transmit port of a high speed interface such as PCIe. This path starts at the CPU at 103 with an MMIO WRITE command and ends at the transmit port with a memory read command 111. The command is then looped back into the input port and shown as an upwards path. In the upwards path, the memory READ header at the input port 117 is sent to an upstream PCIe memory read function 119. This function is typically transmitted into the core and actually is processed by a CPU core to read memory out of system memory such as DDR (Double Data Rate) memory. The WRITE command can also be translated at the header ATM into a different type of READ command, such as a DMI (Direct Media Access) port READ command and then looped back to be a READ to the DDR. The DDR READ command can be intercepted by test equipment or counted using a separate program executed within the CPU. As an alternative, a MMIO READ command may be used instead of an MMIO WRITE command. A similar translation and loopback may used to test the handling of MMIO WRITE commands. Similarly a DMI WRITE or READ command may be applied to the DMI ports and looped back to test operation of the DMI ports and of the transmit and receive lines.

The loop back 115 can be implemented in a variety of different ways as described in more detail below. A switchable jumper on the die can be used. Alternatively, a jumper can be attached to the die or to a socket into which the die has been inserted. As a further alternative, the die may be installed onto a motherboard or into a socket on a motherboard and the loop back can be performed using a special card. In one example, the operations of FIG. 1 are used to test a PCIe interface which typically will be coupled through a motherboard to a PCIe slot. A special test PCIe adapter card can be installed into the slot which has the sole function of looping back signals transmitted to the PCIe card to a corresponding PCIe receive port. The adapter card is, in effect, a jumper for the ports on the slot. As a further alternative, a special slot may be used that performs the loop back without using a card. The slots and cards can conform to a variety of form factors including mini-PCIe. By adding a motherboard, a slot, and a card inserted into the slot, more of the PCIe communications hardware can be tested using the loop back techniques described herein. On the other hand, by providing a loop back mechanism on the die, the die can be tested without the interoperation of any other components so that faults can be more accurately isolated. The particular hardware used for any on particular test may be adapted to suit the purposes of the particular test.

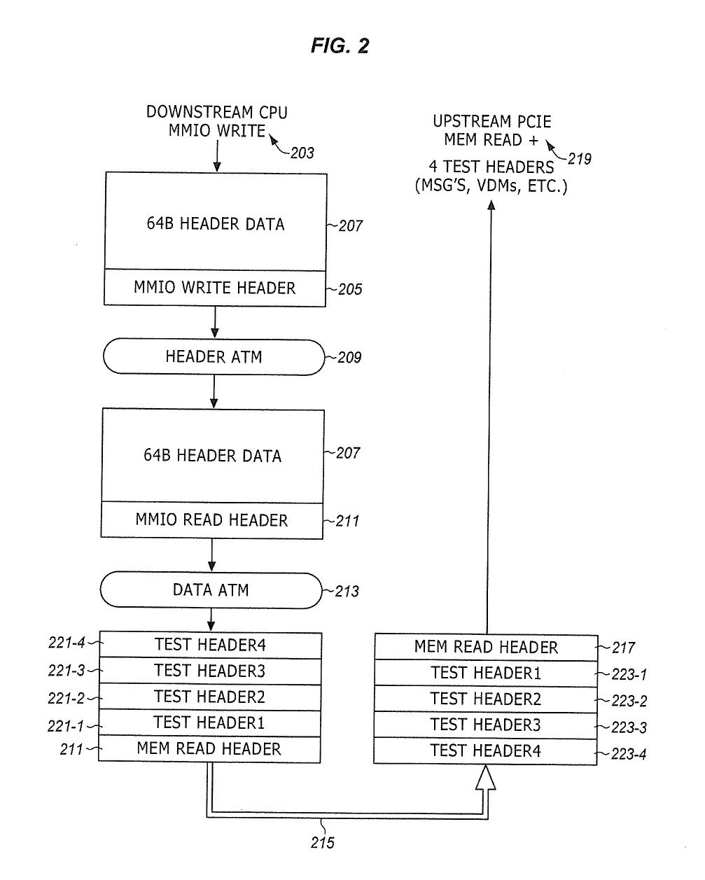

FIG. 2 is a message transactional diagram to show an example of using a CPU core to create and format any PCIe request type, write this to MMIO, and have it appear on the Rx path as if a PCIe device had generated multiple requests.

FIG. 2 shows a diagram of a second embodiment of a loop back test operation. As in the example of FIG. 1, the CPU generates a downstream test packet, for example a MMIO WRITE 203. In this example, the WRITE has an MMIO WRITE header 205 and 64 bytes of header data 207. A header ATM 209 converts the MMIO WRITE header into a memory READ header 211 but does not affect the 64 bytes of header data 207. A data ATM 213 converts the 64 bytes of header data into a sequence of test headers 221-1 to 221-4. This entire test packet is looped back through a loop back mechanism similar to that of FIG. 1 and then sent on the input port as a memory READ header 217, test headers 223-1 to 223-4.

In one example, the test headers are additional memory READ commands. In another example, the test headers are directed to another external device such as another PCIe interface or to internal or external graphics. In another example, the test headers are vendor defined messages (VDM) in the PCIe context that can relate to identification, operation, or use of attached PCIe peripheral devices.

In the upstream path, the upstream test packet received at the core 219 consists of a memory READ command plus 4 test headers. As in FIG. 1, the MMIO WRITE header and the 64 bytes of header data can be selected to easily be converted into the test messages that are looped back onto the return path. This allows the header ATM and the data ATM to be implemented using simple hardware logic. In one embodiment, the header ATM and the data ATM are a single block of hardware logic which converts all of the bytes into the looped back form in one operation.

In FIG. 1 a single memory read command 117 is applied to a CPU core to cause the CPU core to read from its system memory. However, in FIG. 2 a more complex set of commands can be sent on the input port through the loop back. In addition to the memory READ header 217, four other messages are shown. There may be more or fewer messages depending upon the particular size of the original header data 207 and the types of commands which are to be sent to the CPU. In one example, the test headers are messages and vendor defined messages that simulate messages that can be created by a graphics processing unit. Alternatively, these messages can be chipset messages that might be generated by, for example, an I/O controller hub.

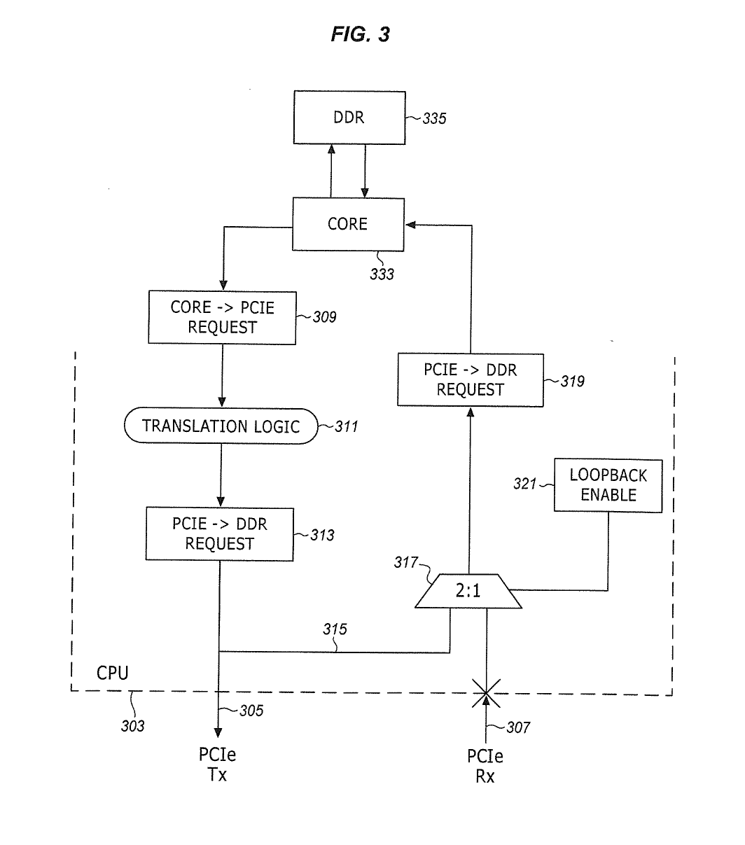

FIG. 3 shows one example of a loop back test system implemented in hardware. In the block diagram of FIG. 3, a CPU 303 has a PCIe transmit port 305 and a PCIe receive port 307. These are intended to be connected to a PCIe external device of any type. A single line for transmit and for receive is shown. This suggests a single lane of PCIe, however, similar techniques may be applied to more lanes of PCIe which is directly or indirectly connected to the CPU 303. The CPU core 333 generates a request 309 which is sent through translation logic 311 coupled to the core where it is converted, as described above, into a memory request 313 for example to DDR memory 335. This message is coupled to the PCIe transmit port, however, a loopback line 315 also couples the PCIe transmit to the PCIe receive 307 through a multiplexer 317.

The multiplexer 317 has two inputs. One input is the PCIe transmit output loopback line 315. The other input is the PCIe receive line 307. The multiplexer's output is the PCIe receive line to the core, shown as carrying a DDR request 319 which is sent up to the core 309. The multiplexer 317 is controlled by a loop back enable line 321 into the multiplexer. The enable line determines which of the two inputs is transmitted up to the core. The enable line may be controlled by an external pin or by setting an internal configuration register, or in other ways. The loopback line 315, enable pin 321, and multiplexer 317 allow the CPU 303 to switch from normal operation in which the PCIe input receives data externally to the loopback operation shown in FIGS. 1 and 2.

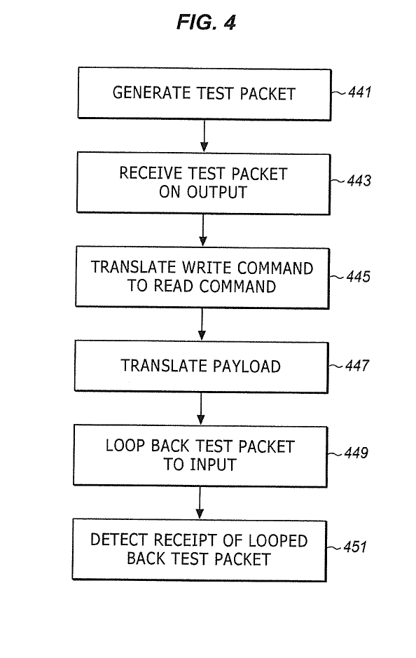

FIG. 4 is a process flow diagram of testing a CPU using the techniques and operations described above. At 441 the CPU generates a test packet. This test packet is then received at 443 on an output of a high speed data interface, for example PCIe or DMI. At 445 the test packet is translated. In one example, the WRITE command is translated into a READ command and at 447 the payload for the test packet is also translated. As described above, the payload may be simply removed as in FIG. 1 or it may be converted into other types of signals including vendor defined messages as shown in FIG. 2. The translated command and payload are then looped back at 449 to the input of the high speed data interface. Finally, the receipt of the looped back test packet is detected at 451. This may be detected by the CPU or it may be detected by external test equipment coupled to another interface.

The CPU may be caused to generate test packets using any of a variety of different techniques. In one example, the CPU runs a software program that causes it to generate test packets. In another example the instructions to generate test packets are loaded directly into an instruction cache of a core of the CPU so that, upon power up, the CPU runs the loaded instruction cache directly without boot up or software being used. These two different techniques allow different aspects of the CPU and system operation to be tested independently of each other.

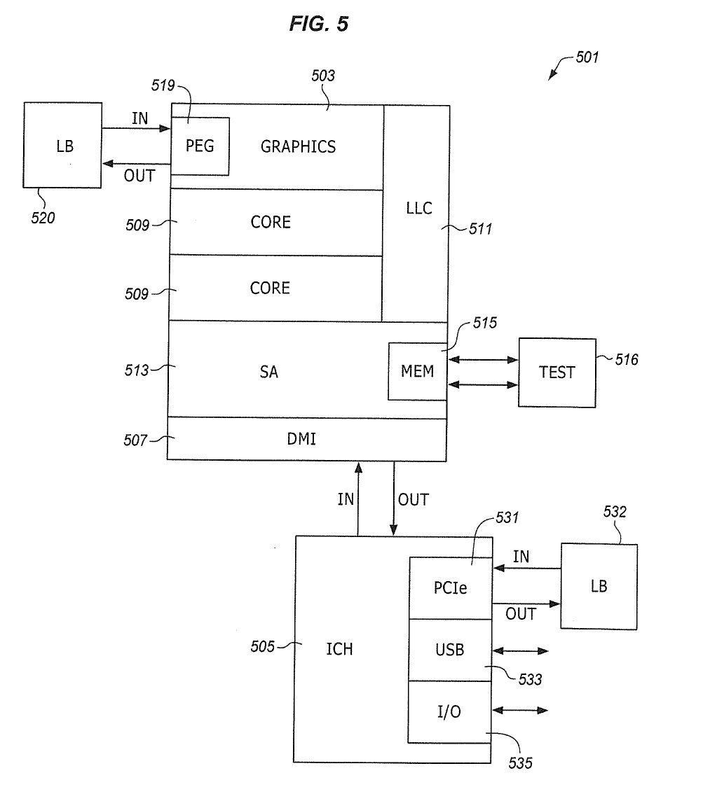

Referring to FIG. 5, the graphics core 201 is shown as part of a larger computer system 501. The computer system has a CPU 503 coupled to an input/output controller hub (ICH) 505 through a DMI (Direct Media Interface) 507. The CPU has one or more cores for general purpose computing 509 coupled to the graphics core 201 and which share a Last Level Cache 511. The CPU includes system agents 513 such as a memory interface 515, and a PCIe graphics interface 519. In the illustrated example, the PCIe interface is for PCI express graphics and can be coupled to a graphics adapter which can be coupled to a display (not shown). The PCIe graphics interface can alternatively be coupled to other PCIe devices and interfaces, such as high speed storage or communications. The memory interface 515 is to be coupled to system memory.

The input/output controller hub 505 includes interfaces to additional PCIe devices 531, universal serial bus devices 533, and other external peripheral input/output devices 533. These interfaces are used for mass storage, displays, and user input/output devices, such as a keyboard and mouse. The input/output controller hub may also include a display interface and other additional interfaces.

The loop back connectors described above may be integrated into the CPU 503 and the ICH 505 as shown, for example, in FIG. 3. FIG. 5 shows an alternative in which a loopback connector 520 is coupled to the PCIe graphics interface 519. A second loop back connector 532 is coupled to the PCIe interface of the ICH. These loop back connectors may be separate external devices that connect directly to the interface to act simply as jumpers to connect the input to the output. Alternatively, if the chips are connected to a printed circuit board, then the loopback connectors may be separate devices also coupled to the printed circuit board so that signals from the PCIe output are conducted on the board to the separate loop back connector. The separate loop back connector may be a slot and adapter card or jumpers installed into a fixture or wiring shunts on the motherboard. As another alternative, the loop back connectors may be integrated into special purpose sockets. The chip is inserted into the socket and the socket contains a conductor between the PCIe input and output ports.

The CPU 503 also includes a DMI interface which is a second high speed interface between the CPU and the ICH. This interface may be tested in the same way as the PCIe interface. Other interfaces such as USB and Thunderbolt may be tested using approaches similar to those described herein.

The memory interface 515 is shown coupled to a test device 516. In the example described above, the CPU core that initiates the test packets also receives the looped back test packets and can count and compare the input packets received to the output packets that it generated. In another example, a test detector 516 is coupled to the system memory interface. If the output test packets are looped back as MEM READ commands, then those commands will be sent to the MEM interface 515. The test detector 516 can detect those commands as they are placed on the memory interface bus.

While the CPU and ICH are shown as coupled together, each can be tested without being connected to the other. The DMI interface of the CPU can be tested by connecting a loop back connector instead of the ICH. Alternatively, an internal loop back connection as shown in FIG. 3 can be used. The ICH can be tested by sending messages through the DMI input to be looped back at the PCIe or other interfaces of the ICH. This can be done without a CPU.

A wide range of additional and alternative devices may be coupled to the computer system 501 shown in FIG. 5. Alternatively, the embodiments of the present invention may be adapted to different architectures and systems than those shown. Additional components may be incorporated into the existing units shown and more or fewer hardware components may be used to provide the functions described. One or more of the described functions may be deleted from the complete system.

It is to be appreciated that a lesser or more equipped system than the examples described above may be preferred for certain implementations. Therefore, the configuration of the exemplary systems and circuits may vary from implementation to implementation depending upon numerous factors, such as price constraints, performance requirements, technological improvements, or other circumstances.

Embodiments may be implemented as any or a combination of: one or more microchips or integrated circuits interconnected using a motherboard, hardwired logic, software stored by a memory device and executed by a microprocessor, firmware, an application specific integrated circuit (ASIC), and/or a field programmable gate array (FPGA). The term “logic” may include, by way of example, software or hardware and/or combinations of software and hardware.

References to “one embodiment”, “an embodiment”, “example embodiment”, “various embodiments”, etc., indicate that the embodiment(s) of the invention so described may include particular features, structures, or characteristics, but not every embodiment necessarily includes the particular features, structures, or characteristics. Further, some embodiments may have some, all, or none of the features described for other embodiments.

In the following description and claims, the term “coupled” along with its derivatives, may be used. “Coupled” is used to indicate that two or more elements co-operate or interact with each other, but they may or may not have intervening physical or electrical components between them.

As used in the claims, unless otherwise specified the use of the ordinal adjectives “first”, “second”, “third”, etc., to describe a common element, merely indicate that different instances of like elements are being referred to, and are not intended to imply that the elements so described must be in a given sequence, either temporally, spatially, in ranking, or in any other manner.

The drawings and the forgoing description give examples of embodiments. Those skilled in the art will appreciate that one or more of the described elements may well be combined into a single functional element. Alternatively, certain elements may be split into multiple functional elements. Elements from one embodiment may be added to another embodiment. For example, orders of processes described herein may be changed and are not limited to the manner described herein. Moreover, the actions any flow diagram need not be implemented in the order shown; nor do all of the acts necessarily need to be performed. Also, those acts that are not dependent on other acts may be performed in parallel with the other acts. The scope of embodiments is by no means limited by these specific examples. Numerous variations, whether explicitly given in the specification or not, such as differences in structure, dimension, and use of material, are possible. The scope of embodiments is at least as broad as given by the following claims.

What is claimed is:

1. A method comprising:
receiving a test packet on an output of a high speed processor link;
looping the test packet back to an input of the high speed processor link; and
detecting the receipt of the looped back test packet to test operation of the high speed link.

2. The method of claim 1, wherein looping back comprises conducting the test packet from an output pin of the processor to a corresponding input pin of the processor.

3. The method of claim 2, wherein looping back comprises conducting the test packet from an output pin of the processor through a circuit board to which the processor is connected to a jumper coupled to the corresponding input pin.

4. The method of claim 1, wherein looping back comprises applying the test packet to an input of a multiplexer of the processor, the multiplexer also having the input of the high speed processor link as an input, and selecting the looped back test packet input of the multiplexer.

5. The method of claim 1, wherein the test packet comprises a header having a write command to an external component, the method further comprising translating the write command to a read command before looping back.

6. The method of claim 5, wherein translating the write command comprises performing a simple logical operation on the write command.

7. The method of claim 5, wherein the test packet comprises a payload of data to support the write command and wherein the translating comprises removing the payload from the test packet.

8. The method of claim 5, wherein the test packet comprises a payload of data to support the write command and wherein translating comprises translating the write command to additional read commands.

9. The method of claim 8, wherein the read commands are commands to read from associated system memory coupled the processor through a different high speed link.

10. An apparatus comprising:
a high speed communications link of a processor having an output and an input;
a core of the processor to generate requests for transmission through the output of the high speed external link; and
a selectable loop back connector to connect the output of the high speed external link to the input of the high speed external link.

11. The apparatus of claim 10, further comprising an enable connector to selectively enable and disable the loop back connector.

12. The apparatus of claim 10, further comprising translation logic to convert a header of the test packet from one type to another type.

13. The apparatus of claim 12, wherein the translation logic is to receive a WRITE command to an external device suitable for transmission through the output of the high speed external link and to translate the WRITE command to a READ command suitable for receipt through the input of the high speed external link.

14. The apparatus of claim 12, wherein the translation logic comprises an XOR circuit.

15. The apparatus of claim 12, wherein the translation logic is further to convert a payload of the test packet to commands.

16. The apparatus of claim 10, wherein the loop back connector comprises a multiplexer of the processor having the output as a first input and the input as a second input.

17. The apparatus of claim 10, wherein the loop back connector comprises a trace on a circuit board coupled to a slot connected to the circuit board and an adapter card installed in the slot.

18. An apparatus comprising:
a peripheral component interface-express (PCIe) link of a processor having an output and an input for at least one lane;
a core of the processor to generate memory mapped input output write requests for transmission through the output of the PCIe link;
translation logic to translate the write requests to memory read requests directed to system memory coupled to the core; and
a selectable loop back connector to connect the output of the PCIe link to the input of the PCIe link.

19. The apparatus of claim 18, wherein the write requests further comprise data for the write request, the method further comprising translating the data to test headers to be applied to the core.

20. The apparatus of claim 19, wherein the test headers comprise vendor defined messages under the PCIe context.
